(19) United States
(12) Patent Application Publication
(10) Pub. No.: US 2020/0066969 A1
(43) Pub. Date: Feb. 27, 2020

(54) PERPENDICULAR MRAM FREE LAYER WITH NB OXIDE CONTAINING CAPPING LAYER

(71) Applicant: International Business Machines Corporation, Armonk, NY (US)

(72) Inventor: Matthias Georg GOTTWALD, New Rochelle, NY (US)

(21) Appl. No.: 16/112,075

(22) Filed: Aug. 24, 2018

(51) Int. Cl. H01L 43/02; H01L 43/10; H01L 43/12; H01L 27/22; H01F 10/32; H01F 41/30

(52) U.S. Cl. CPC H01L 43/02; H01L 43/10; H01F 41/302; H01L 27/222; H01F 10/3286; H01L 43/12

(57) ABSTRACT

A magneto resistive random access memory (MRAM) structure and method for making the same. The MRAM structure includes: a magnetic free layer, an oxidized Niobium (Nb) capping layer over the magnetic free layer, and a nonmagnetic insulating tunnel barrier layer in between the magnetic free layer and a magnetic metal reference layer.

### BACKGROUND

The present invention relates to magneto resistive random access memory (MRAM), and more specifically, to forming an MRAM device on top of a silicon stud grown by selective epitaxial growth (SEG).

A spin torque magnetic random access memory (MRAM) device uses a two terminal spin-torque based memory element. The two terminal spin-torque based memory element includes a pinned layer, a tunnel barrier layer, and a free layer in a magnetic tunnel junction (MTJ) stack. The pinned layer is also called the reference layer. The magnetization of the pinned layer is fixed in a direction such that when current passes through the MTJ stack the free layer becomes either parallel or anti-parallel to the pinned layer. Resistance of the device depends on the relative orientation of the free layer and the pinned layer.

### SUMMARY

According to one embodiment of the present invention, a method is provided. The method includes: depositing a reference layer on a substrate, depositing a tunnel barrier layer over the reference layer, depositing a free layer over the tunnel barrier layer, and depositing a niobium (Nb) capping layer over the free layer.

According to another embodiment of the present disclosure, a structure is provided. The structure includes: A magneto resistive random access memory (MRAM) structure including: a magnetic free layer, an oxidized Niobium (Nb) capping layer over the magnetic free layer, and a nonmagnetic insulating tunnel barrier layer in between the magnetic free layer and a magnetic metal reference layer.

### BRIEF DESCRIPTION OF THE SEVERAL VIEWS OF THE DRAWINGS

FIG. 1A illustrates a memory structure according to at least one embodiment of the present disclosure.

FIG. 1B illustrates a memory structure according to at least one embodiment of the present disclosure.

FIG. 2 illustrates a memory structure according to at least one embodiment of the present disclosure.

FIG. 3 illustrates a memory structure according to at least one embodiment of the present disclosure.

FIG. 4 illustrates a flow for forming a memory structure according to an embodiment of the present disclosure.

### DETAILED DESCRIPTION

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. For purposes of the description hereinafter, the terms “upper”, “lower”, “right”, “left”, “vertical”, “horizontal”, “top”, “bottom”, and derivatives thereof shall relate to the embodiments of the disclosure, as it is oriented in the drawing figures. The terms “positioned on” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

As used herein, the term “memory device” is a structure in which the electrical state can be altered and then retained in the altered state, in this way a bit of information can be stored. Spin torque transfer magnetic random access memory (STT MRAM) uses magnetic materials as the memory storage element. In some examples, STT MRAM uses memory storage elements that take advantage of the effect in which a current that is passed through a magnetic material, such as a magnetic tunnel junction (MTJ)—reverses its direction of magnetization. Passing a current through the MTJ causes its direction of magnetization to switch between a parallel or anti-parallel state, which has the effect of switching between low resistance and high resistance. Because this can be used to represent the 1s and 0s of digital information, STT MRAM can be used as a non-volatile memory. Reading STT MRAM involves applying a voltage to the MTJ to discover whether the MTJ offers high resistance to current (“1”) or low (“0”). A MTJ stack can include reference layer(s) (also referred to as pinned layer), tunnel layer(s) and free layer(s). A MTJ stack can be configured such that either or both of the reference layer and tunnel barrier are disposed beneath the free layer.

It should be noted that exemplary materials for the free layer(s) include alloys and/or multilayers of iron (Fe), nickel (Ni), cobalt (Co), chromium (Cr), vanadium (V), manganese (Mn), palladium (Pd), platinum (Pt), boron (B), oxygen (O) and/or nitrogen (N). Moreover, the tunnel barrier layer(s) can be composed of magnesium-oxide (MgO), aluminum-oxide (Al₂O₃), titanium-oxide (TiO₂), or materials of higher electrical tunnel conductance, such as semiconductors or low-bandgap insulators.

In some embodiments, a spin torque MRAM uses a two terminal device with a pinned layer, tunnel barrier, and free layer in a magnetic tunnel junction stack. The magnetization of the pinned layer is fixed in direction (say pointing up) and a current passed down through the junction makes the free layer parallel to the pinned layer, while a current passed up through the junction makes the free layer anti-parallel to the pinned layer. A smaller current (of either polarity) is used to read the resistance of the device, which depends on the relative orientations of the magnetizations of the free and pinned layers. The resistance is typically higher when the magnetizations are anti-parallel and lower when they are parallel (though this can be reversed, depending on the material). It has been determined that one of the challenges in spin torque MRAM devices is to lower the switching current.

In some embodiments, the methods and structures of the present disclosure replace the tunnel barriers and pinned layers with magnetic insulating tunnel barrier reference layers. These layers are both magnetic and insulating, and are commonly referred to as spin filters. The term “magnetic” as used to describe the spin filter material layer, which is also referred to as a magnetic insulating tunnel barrier reference layer, may have a magnetization ranging from 50 emu/cm³ to 600 emu/cm³. The term “insulating” as used to describe the spin filter material layer, which is also referred to as a magnetic insulating tunnel barrier reference layer, may denote a material having a room temperature resistance-area product of more than 0.1 Ohm-um2.

In one or more embodiment of the present disclosure include a structure employing a niobium (Nb) capping layer for perpendicular MTJ (“pMTJ) devices, and methods for making the same. In one or more embodiments, employing Nb as a capping layer materials increases perpendicular magnetic anisotropy. In one embodiment, the increased perpendicular magnetic anisotropy and other benefits are achieved because the weight of Nb is such that it provides suitable magnetic and electrical properties, while being light enough so that a capping layer composed of Nb does not intermix with free layers of a pMTJ device, including cobalt-iron-boride (CoFeB) free layers.

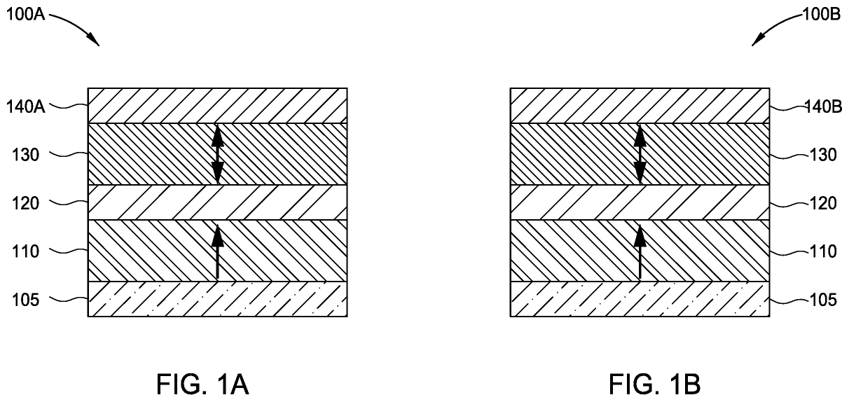

FIG. 1A illustrates a memory device 100A with a niobium capping layer in accordance with at least one embodiment of the present disclosure. In one embodiment a perpendicular MTJ (“pMTJ”) reference layer 110 is deposited on a substrate 105, wafer 105, or material 105 using any suitable deposition technique, including but not limited to sputtering and chemical vapor deposition (CVD), where the substrate can be any suitable material or apparatus for a pMTJ structure. The reference layer 110 can be a layer composed of alloys and/or multilayers of iron (Fe), nickel (Ni), cobalt (Co), chromium (Cr), boron (B), manganese (Mn), platinum (Pt), palladium (Pd), ruthenium (Ru), iridium (Ir), tantalum (Ta), W (tungsten) and/or Cu (copper). In one embodiment, in order to form the reference layer 110, a CoPt, CoNi, and/or CoIr material is deposited on a seed layer that includes a composition of one of or both of Ta and Ru, where the seed layer is between 5 nm and 10 nm in thickness. In one embodiment, a spin polarization enhancement layer (not shown) is part of the reference layer 110, where the spin polarization enhancement layer can be a CoFeB layer or a W and CoFeB bilayer, and where the spin polarization enhancement layer is also deposited using physical layer deposition or sputtering. In one embodiment, the CoFeB reference layer 110 is less than or equal to sixty percent B.

In one embodiment, a nonmagnetic insulating tunnel barrier layer 120 (“tunnel barrier layer 120”) is deposited over the reference layer 110 using any suitable deposition techniques, including but not limited to sputtering, e.g. radiofrequency sputtering, or physical vapor deposition. In one embodiment, the tunnel barrier layer 120 adds anisotropy to the multilayer structure. In one embodiment, a suitable material for the tunnel barrier layer 120 includes magnesium oxide (MgO).

In one embodiment, a free layer 130 is formed over the tunnel barrier layer 120 using any suitable deposition technique, including sputtering or physical deposition. The free layer can be any suitable magnetic material, including alloys and/or multilayers of iron (Fe), nickel (Ni), cobalt (Co), chromium (Cr), boron (B), manganese (Mn), platinum (Pt), vanadium (V), palladium (Pd), boron (B), oxygen (O), and/or nitrogen (N). In one embodiment, the free layer 130 is a CoFeB free layer.

In one embodiment, a niobium (Nb) capping layer 140 is deposited over the free layer 130 using any suitable deposition technique, including PVD or sputtering. In one embodiment, the deposited Nb capping layer is between 1 A (angstrom) to 10 A in thickness, including one embodiment where the Nb capping layer is between 2 A to 4 A in thickness. In one embodiment, in order to achieve a thickness of 2 A to 4 A, a sputtering process at less than half an A per second is applied. The Nb capping layer 140 provides improved perpendicular magnetic anisotropy without interfering or intermixing with other layers of the device, e.g. free layer 130, because of the weight associated with Nb. Additionally, in the embodiment where the capping layer is between 2 A and 4 A in thickness, at least one additional benefit is also provided, e.g. during any subsequent oxidation steps, the reduced thickness will mitigated adverse effects associated with the increase of electrical resistance associated with oxidation.

In one embodiment, as show in FIG. 1B, the Nb capping layer 140 is oxidized by having the device 100, and any underlying wafer (not shown) or substrate (not shown) associated with the device 100 exposed to oxygen (O₂) using any suitable oxidation process, including natural oxidation or deposition, resulting in structure 100B. In one embodiment, after oxidation, the Nb capping layer 140B will be between 10 A and 12 A in thickness, having been between 2 A and 4 A in thickness prior to oxidation. In one embodiment, the thickness of the Nb oxidized capping layer 140B, e.g. 10 A to 12 A, provides sufficient perpendicular magnetic anisotropy due to the nature of Nb, while minimizing the electrical resistance by having a thin oxidize capping layer 140B composed of Nb. In one embodiment, the oxidation takes place for a time period of 10 seconds (s) to 10,000 s.

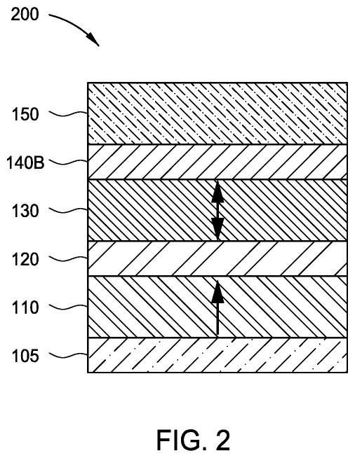

FIG. 2 illustrates depositing an affinity layer 150, e.g. low oxygen affinity layer 150, over the oxidized Nb capping layer 140B according to an embodiment of the present disclosure, resulting in structure 200. Any suitable deposition technique can be used to deposit the affinity layer 150, including PVD and sputtering. The affinity layer 150 can be made of alloys or multilayers of (Fe), nickel (Ni), cobalt (Co), chromium (Cr), boron (B), manganese (Mn), platinum (Pt), palladium (Pd), ruthenium (Ru), iridium (Ir), tantalum (Ta), W (tungsten) and/or Cu (copper). In one embodiment, the affinity layer 150 can be between 10 A and 200 A in thickness.

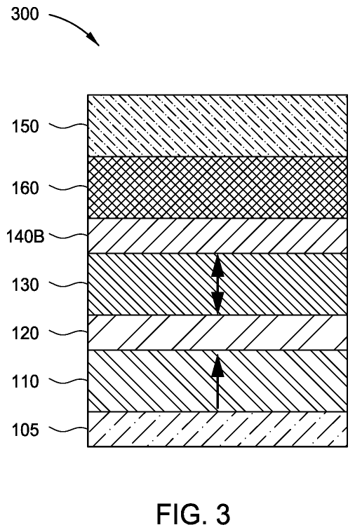

FIG. 3 illustrates depositing a magnetic dummy layer in accordance to at least one embodiment of the present disclosure over the oxidized Nb capping layer 140B, resulting in structure 200. In one embodiment, prior to forming the affinity layer 150, the magnetic dummy layer 160 is deposited over the oxidized Nb capping layer 140B using any suitable deposition technique, including PVD and sputtering. The magnetic dummy layer 160 can be composed from any material as disclosed herein or otherwise suitable for functioning as a magnetic dummy layer 160, including CoPt, CoNi, CoIr, and/or CoFeB. In one embodiment, the magnetic dummy layer is a CoFeB free layer 160. In one embodiment the CoFeB layer is between 3 A and 10 A in thickness.

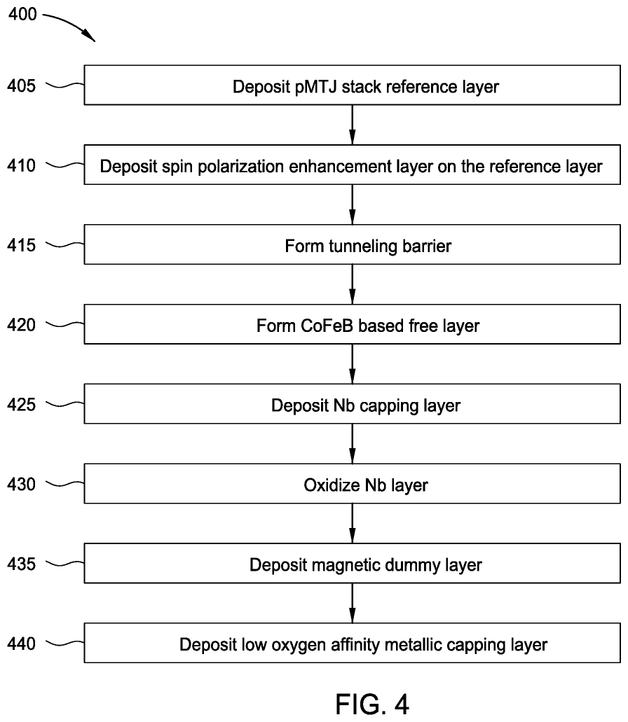

FIG. 4 illustrates at least one flow 400 for forming a pMTJ device at any suitable manufacturing facility and in accordance with at least one embodiment of the present disclosure. In block 405 a pMTJ stack is formed with a reference layer 110 composed of a suitable material, e.g. CoPt, CoNi, CoIr, and/or CoFeB, which is deposited on a seed layer composed of a suitable material, e.g. Ta or Ru, and on a suitable CMOS wafer or substrate, where, in one embodiment, the substrate or wafer can be 5 nanometers (nm) to 10 nm in thickness. The deposition can be by any suitable means, including sputtering or PVD.

In one embodiment, per block 410, a spin-on-enhancement layer (not shown) is deposited on or is part of the reference layer 110 when formed, e.g. a CoFeB layer or a W/CoFeB bilayer. In one embodiment, per block 415, an MgO tunnel barrier layer 120 is formed over the reference layer 110 using any suitable deposition technique, e.g. PVD or sputtering.

In one embodiment, per block 420, a CoFeB free layer 130 is deposited or grown over the MgO tunnel barrier layer 120 using any suitable deposition technique, including sputtering or PVD. In one embodiment, per block 425, an Nb capping layer 140 is deposited over the CoFeB free layer 130. The Nb capping layer 140 can be deposited using any suitable technique, including PVD or sputtering, where in one embodiment the Nb capping layer is between 2 A and 4 A in thickness and formed by sputtering at a rate of half an A per second.

In one embodiment, per block 430, the Nb capping layer 140 is oxidized to become an oxidized Nb capping layer 140B. In one embodiment, the oxidized Nb capping layer 140B can be formed using any suitable oxidation process, including natural oxidation, where the oxidation takes place for a period of 10 s-10,000 s to form an oxidized Nb capping layer 140B with a thickness of 10 A to 12 A.

In one embodiment, per block 435, the a magnetic dummy layer 160 composed of CoFeB is deposited over the oxidized Nb capping layer 140B, where, in one embodiment, the CoFeB dummy layer 160 can be between 3 A and 10 A in thickness. In one embodiment, per block 440, a low oxygen affinity layer 150 can be deposited over the magnetic dummy layer 160 using any suitable deposition technique, including PVD and sputtering. In one embodiment, the affinity layer 140 can be made of alloys or multilayers of (Fe), nickel (Ni), cobalt (Co), chromium (Cr), boron (B), manganese (Mn), platinum (Pt), palladium (Pd), ruthenium (Ru), iridium (Ir), tantalum (Ta), W (tungsten) and/or Cu (copper). In one embodiment, the affinity layer 150 can be between 10 A and 200 A in thickness.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any

While the foregoing is directed to embodiments of the present invention, other and further embodiments of the invention may be devised without departing from the basic scope thereof, and the scope thereof is determined by the claims that follow.

1. A method comprising:
depositing a reference layer on a substrate;
depositing a tunnel barrier layer over the reference layer;
depositing a free layer over the tunnel barrier layer; and
depositing a niobium (Nb) capping layer over the free layer.

2. The method of claim 1, wherein the Nb capping layer is between 2 angstrom (A) and 4 A in thickness.

3. The method of claim 2 further comprising:
forming the Nb capping layer by sputtering at a rate of less than half an A per second (s).

4. The method of claim 1 further comprising:
oxidizing the Nb capping layer.

5. The method of claim 4, wherein the oxidized Nb capping layer is between 10 A and 12 A in thickness.

6. The method of claim 1, wherein prior to the oxidation, the Nb capping layer is between 2 A and 4 A in thickness and the Nb capping layer is formed by sputtering at a rate of half an A per s, and wherein after the oxidation, the oxidized Nb capping layer is between 10 and 12 A in thickness.

7. The method of claim 4 further comprising:
depositing a low oxygen affinity layer over the Nb capping layer.

8. The method of claim 4 further comprising:
depositing a magnetic dummy layer over the Nb capping layer; and
depositing a low oxygen affinity layer over the magnetic dummy layer.

9. The method of claim 8, wherein the tunnel barrier layer comprises magnesium-oxide (MgO), the free layer comprises cobalt-iron-boride (CoFeB), the magnetic dummy layer comprises CoFeB, and wherein the free layer comprises at least one of: iron (Fe), nickel (Ni), cobalt (Co), chromium (Cr), vanadium (V), manganese (Mn), palladium (Pd), platinum (Pt), boron (B), oxygen (O) and/or nitrogen (N).

10. The method of claim 9, wherein the oxidized Nb capping layer is between 10 A and 12 A, and wherein the both the free layer and the tunnel barrier layer are composed of less than sixty percent of boron.

11. A magneto resistive random access memory (MRAM) structure comprising:
a magnetic free layer comprising cobalt-iron-boride (CoFeB);
an oxidized Niobium (Nb) capping layer directly contacting the magnetic free layer, wherein the oxidized Nb capping layer provides improved perpendicular magnetic anisotropy without interfering or intermixing with other layers of the MRAM structure; and
a nonmagnetic insulating tunnel barrier layer between the magnetic free layer and a magnetic metal reference layer.

12. The structure according to claim 11, wherein the oxidized Nb capping layer is between 1 angstrom and 10 angstroms in thickness.

13. The structure according to claim 12, wherein the oxidized Nb capping layer is between 2 angstroms and 6 angstroms in thickness.

14. The structure of claim 11, further comprising:
a second capping layer disposed on the oxidized Nb capping layer, wherein the oxidized Nb capping layer is between the second capping layer and the magnetic free layer.

15. The structure of claim 14, wherein the second capping layer is a low oxygen affinity capping layer and directly contacts the oxidized Nb capping layer.

16. The structure of claim 15, wherein the second capping layer comprises at least one of Ruthenium (Ru) and Iridium (IR).

17. The structure of claim 15, wherein the free layer contains less than sixty percent in boron.

18. The structure of claim 15, wherein the free layer is between 3 angstroms and 10 angstroms in thickness.

19. The structure of claim 11 further comprising:
a magnetic dummy layer in contact with the oxidized Nb capping layer.

20. The structure of claim 19 further comprising:
a second capping layer, wherein the magnetic dummy layer is between the Nb capping layer and the second capping layer.

21. A magneto resistive random access memory (MRAM) structure consisting of:
a magnetic free layer;
an oxidized Niobium (Nb) capping layer in direct contact with the magnetic free layer, wherein the oxidized Nb capping layer is between 2 angstroms and 4 angstroms in thickness; and
a nonmagnetic insulating tunnel barrier layer between the magnetic free layer and a magnetic metal reference layer.
